(19) United States
(12) Patent Application Publication
(10) Pub. No.: US 2009/0255804 A1
(43) Pub. Date: Oct. 15, 2009

(54) PIEZOELECTRIC FILM FORMING METHOD

(76) Inventors: Takayuki NAONO, Kanagawa-ken (JP); Takamichi FUJII, Kanagawa-ken (JP)

Correspondence Address: BIRCH STEWART KOLASCH & BIRCH, PO BOX 747, FALLS CHURCH, VA, 22040-0747, US

(21) Appl. No.: 12/420,348

(22) Filed: Apr. 8, 2009

(30) Foreign Application Priority Data
Apr. 9, 2008 (JP) 101822/2008

(51) Int. Cl. C23C 14/34

(52) U.S. Cl. 204/192.18

(57) ABSTRACT

When forming a piezoelectric film of a Pb containing perovskite-type oxide on a substrate by sputtering, forming the film under a film forming condition in which a film forming temperature Ts(° C.) and a surface potential Vsub of the substrate satisfy Formulae (1) and (2) below respectively.

400=Ts (° C.)=550 (1)

−10=Vsub (V)<100 (2)

### BACKGROUND OF THE INVENTION

1. Field of the Invention

The present invention relates to a piezoelectric film forming method based on sputtering using plasma.

2. Description of the Related Art

Piezoelectric devices which include a piezoelectric film having piezoelectricity, in which the film stretches or contracts according to the applied electric field strength, and an electrode for applying an electric field to the film are used as an actuator mounted on an inkjet recording head and the like. As for piezoelectric materials, perovskite oxides, such as lead zirconate titanate (PZT) system and the like are known.

Piezoelectric films can be formed by chemical vapor deposition methods, such as spluttering. For piezoelectric films of Pb containing perovskite oxides, such as PZT and the like, Pb dropout is likely to occur when formed at a high temperature. In addition, it is preferable to grow highly oriented crystals for the PZT perovskite system. Therefore, it is necessary to find out a film forming condition for Pb containing perovskite oxides that allows pyrochlore phase suppressed perovskite crystals to be grown favorably with high orientation and the Pb dropout to be less likely to occur.

For example, in “Fabrication Process of New Ceramic Thin Films—Epitaxial Growth of Compound Thin Films—”, K. Wasa, Ceramics, Vol. 21, No. 2, pp. 119-125, 1986 (Non-Patent Document 1), a favorable film forming condition is sought by sweeping the film forming temperature with other conditions being fixed. FIG. 3 in Non-Patent Document 1 shows that, for a PbTiO₃ film, a pyrochlore phase structure is formed at a temperature lower than about 500° C., a perovskite crystal is grown at a temperature in the range from about 550 to 700° C., and a non-crystal structure is formed at a temperature higher than about 700° C.

Japanese Unexamined Patent Publication No. 6 (1994) -049638 (Patent Document 1) shows the following relationships for a PZT film, that is, the relationship between the film forming pressure and Pb content in the film and the relationship between the film forming temperature and Pb content in the film (FIGS. 1 and 2). Patent Document 1 describes that the film forming pressure is desirable to be in the range from 1 to 100 mTorr, and the film forming temperature to be in the range from 600 to 700° C. (Claims 2 and 5).

Japanese Unexamined Patent Publication No. 2004-119703 (Patent Document 2) proposes a method for reducing, when forming a piezoelectric film, tensile stress on the piezoelectric film by setting the potential of the substrate to a value in the range from −30 to 0V.

Japanese Unexamined Patent Publication No. 5(1993) -078835 (patent document 3) proposes a method for increasing, when forming a piezoelectric film, reproducibility of film property by grounding the substrate or setting the substrate to a certain floating potential.

As described in Non-Patent Document 1 and Patent Document 1, it is said that the desirable temperature range for the film forming is from 550 to 700° C. for piezoelectric films of Pb containing perovskite oxides, such as PZT and the like. The study conducted by the inventors of the present invention, however, has revealed that a pyrochlore phase suppressed perovskite crystal grows and a piezoelectric film having favorable piezoelectric property can be obtained even in the temperature range from about 420 to 480° C. A lower film forming temperature is desirable since the Pb dropout is prevented.

Further, a lower film forming temperature is desirable, because a high film forming temperature causes stress on the piezoelectric film due to difference in thermal expansion coefficient during film formation or in a cooling process after the formation, whereby a crack may sometimes occurs. Still further, a lower film forming temperature is desirable because it provides a wider range of substrate options, such as the use of a comparatively low heat-resistive substrate, such as a glass substrate or the like.

It is thought that a certain factor other than the temperature and pressure is involved in the film forming of a piezoelectric film and a pyrochlore phase suppressed perovskite crystal grows when the factor influencing the film property is in a favorable range.

In the mean time, Patent Documents 2 and 3 propose a method for improving film property by controlling the potential of the substrate and a method for improving reproducibility of film property. In either case, however, the relationship with film orientation, other factors of film forming condition in sputtering are not described.

The present invention has been developed in view of the circumstances described above, and it is an object of the present invention to disclose factors of film forming condition that influence film property in sputtering and to provide, based on this, a film forming method capable of stably forming quality piezoelectric films with high crystalline orientation.

### SUMMARY OF THE INVENTION

The inventors of the present invention earnestly conducted investigations for solving the problems described above, and have found out that the film property of a film to be formed depends largely on a film forming temperature Ts (° C.) and a surface potential Vsub (V) of the substrate, and a quality film can be formed by optimizing these factors, whereby the present invention has been developed.

A film forming method of the present invention is a method for forming a piezoelectric film of one or more types of perovskite oxides represented by General Expression (P) below (which may include an unavoidable impurity) on a substrate by sputtering using plasma,

wherein film forming is performed under a film forming condition in which a film forming temperature Ts (° C.) and a surface potential Vsub of the substrate satisfy Formulae (1) and (2) below respectively.

AₐB_{b}O₃ (P)

(where, A is at least one type of A-site element containing Pb, B is at least one type of B-site element selected from a group consisting of Ti, Zr, V, Nb, Ta, Cr, Mo, W, Mn, Sc, Co, Cu, In, Sn, Ga, Zn, Cd, Fe, and Ni, and O is an oxygen element. Typically, a=1.0 and b=1.0, but these values may deviate from 1.0 within a range in which a perovskite structure is obtainable.)

400=Ts (° C.)=550 (1)

−10 =Vsub (V)<100 (2)

Preferably, the film forming condition satisfies 425=Ts (° C.)=525, and more preferably satisfies 450 =Ts (° C.)=525.

The present invention is preferably applicable to a PZT system represented by General Expression (P-1) below or a B-site substituted PZT system, and a mixed crystal system of these.

Pbₐ(Zr_{b1}Ti_{b2}X_{b3})O₃ (P-1)

(where, X is at least one type of metal element selected from a group consisting of V and VI family elements, and a>0, b1>0, b2>0, and b3=0. Typically, a=1.0 and b1+b2+b3=1.0, but these values may deviate from 1.0 within a range in which a perovskite structure is obtainable.)

The term “film forming temperature Ts (° C.)” as used herein refers to a temperature of the substrate (temperature of the substrate surface on which a piezoelectric film is formed) when the film is formed.

The present invention discloses that the factors of film forming condition that influence the film property in sputtering using plasma are the film forming temperature Ts (° C.) and surface potential Vsub of the substrate.

According to the film forming method of the present invention, film forming is performed under a predetermined film forming condition, so that when forming a piezoelectric film of a Pb containing perovskite oxide, such as PZT or the like, pyrochlore phase suppressed perovskite crystals with high crystal orientation may be grown stably and at the same time Pb dropout may be prevented stably.

### BRIEF DESCRIPTION OF THE DRAWINGS

FIG. 1 is a schematic cross-sectional view of an RF sputtering system.

FIG. 2 schematically illustrates a film forming process.

FIG. 3 is a cross-sectional view of a piezoelectric device and an inkjet recording head (liquid discharge device) according to an embodiment of the present invention, illustrating the structure thereof.

FIG. 4 illustrate an example configuration of an inkjet recorder having the inkjet recording head shown in FIG. 3.

FIG. 5 is a partial top view of the inkjet recorder shown in FIG. 4.

FIG. 6 illustrates an XRD pattern of a major piezoelectric film obtained at Ts=425° C. in Example 1.

FIG. 7 illustrates an XRD pattern of a major piezoelectric film obtained at Ts=450° C. in Example 1.

FIG. 8 illustrates an XRD pattern of a major piezoelectric film obtained at Ts=475° C. in Example 1.

FIG. 9 illustrates an XRD pattern of a piezoelectric film obtained at Ts=450° C. with Vsub=−35V in Comparable Example.

FIG. 10 is a graph that plots XRD measurement results of Example 1, Comparative Example 1, and Comparative Example 2 with the horizontal axis representing film forming temperature Ts and vertical axis representing Vsub.

FIG. 11 is a graph comparing durability between piezoelectric films obtained at Vsub=5V and Vsub=−10V in Example 1.

### DESCRIPTION OF THE PREFERRED EMBODIMENTS

### [Film Forming Method]

A film forming method of the present invention is a method for forming a piezoelectric film of one or more types of perovskite oxides represented by General Expression (P) below on a substrate by sputtering using plasma which is performed under a film forming condition in which film forming temperature Ts (° C.) and surface potential Vsub (V) of the substrate satisfy Formulae (1) and (2) below respectively.

AₐB_{b}O₃ (P)

(where, A is at least one type of A-site element containing Pb, B is at least one type of B-site element selected from a group consisting of Ti, Zr, V, Nb, Ta, Cr, Mo, W, Mn, Sc, Co, Cu, In, Sn, Ga, Zn, Cd, Fe, and Ni, and O is an oxygen element. Typically, a=1.0 and b=1.0, but these values may deviate from 1.0 within a range in which a perovskite structure is obtainable.)

400=Ts (° C.)=550 (1)

−10=Vsub (V)<100 (2)

Preferably, the piezoelectric film has a pillar crystal structure formed of a multiple pillar crystals extending nonparallel to the surface of the substrate. This results in a crystal oriented film in which crystal orientation is aligned, which is preferable since the film can provide high piezoelectric performance. The growth direction of the pillar crystal may be any direction as long as it is nonparallel to the substrate surface, for example, a direction substantially perpendicular or oblique to the substrate surface.

The average pillar diameter of the multiple pillar crystals forming the piezoelectric film does not have any specific limitation, but preferably in the range from 30 nm to 1 μm. An excessively small average pillar diameter results in insufficient crystal growth for a piezoelectric film and desired piezoelectric performance may not be obtained, while an excessively large average pillar diameter may result in degraded shape accuracy after patterning.

For a system including rhombohedral phase (mixed crystal system of tetragonal crystal and rhombohedral crystal, or rhombohedral crystal system), it is preferable that the piezoelectric film has (100) crystal orientation. The spontaneous polarization axis direction of the rhombohedral crystal is <111>, so that the spontaneous polarization has an upward (direction toward film surface from the substrate) vector component when the crystal orientation is (100).

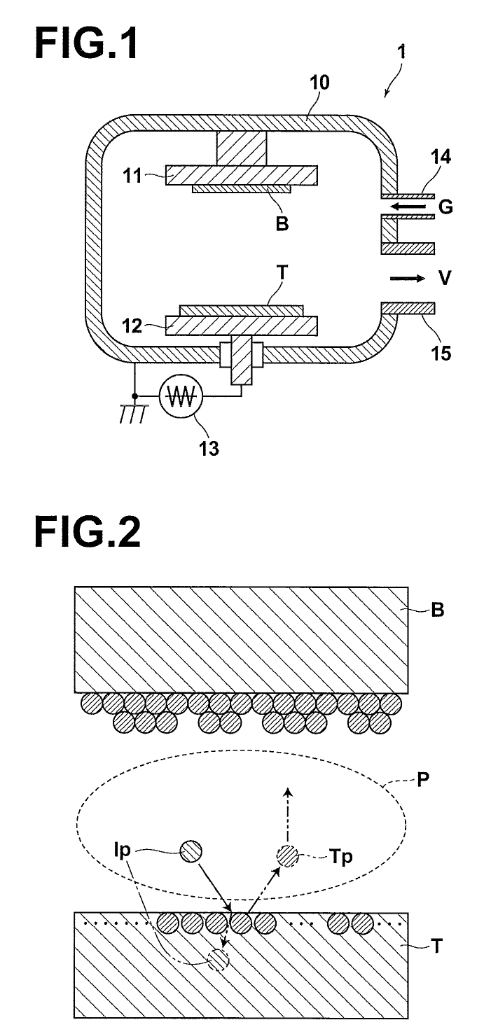

An example configuration of a sputtering system will now be described with reference to FIGS. 1 and 2. FIG. 1 is a schematic cross-sectional view of an RF sputtering system, and FIG. 2 schematically illustrates a film forming process.

RF sputtering system 1 is basically constituted by vacuum vessel 10 having therein heater 11 capable of mounting substrate B and heating mounted substrate B to a predetermined temperature, plasma electrode (cathode electrode) 12 for generating plasma. Heater 11 and plasma electrode 12 are spaced apart and disposed so as to face each other. Plasma electrode 12 is configured to hold composition target T, which is selected according to the composition of a film formed on plasma electrode 12, and connected to high frequency power source 13.

Gas introduction tube 14 for introducing gas G required for film forming and gas discharge tube 15 for discharging exhaust gas V are connected to vacuum vessel 10. As for gas G, Ar, a mixed gas of Ar and O₂, or the like is used. As schematically illustrated in FIG. 2, gas G introduced in vacuum vessel 10 is plasmatized by arc discharging of plasma electrode 12 and positive ion Ip, such as Ar ion, is generated. Generated positive ion Ip is sputtered on target T. Constituent element Tp of target T sputtered by positive ion Ip is released from target T and deposited on substrate B in neutralized or ionized state. Reference symbol P in FIG. 2 represents the plasma space.

The potential of plasma space P corresponds to plasma potential Vp (V). In the present embodiment, RF sputtering system 1 is configured such that surface potential Vsub of substrate B is adjusted to a predetermined potential.

Factors influencing the property of a film formed by sputtering may include film forming temperature, type of substrate, base composition if base film is formed in advance, surface energy of substrate, film forming pressure, amount of oxygen in ambient gas, type of electrode installed, distance between substrate and target, electron temperature and density in plasma, activated species density and lifetime in plasma.

The inventors of the present invention have found out that the property of a formed film depends largely on film forming temperature Ts and Vsub among a variety of factors and a quality film can be formed by optimizing the two factors. That is, the inventors of the present invention plotted the properties of films in a graph with the horizontal axis representing film forming temperature Ts and vertical axis representing Vsub and found out that quality films can be formed in a certain range (FIG. 10).

Japanese Unexamined Patent Publication No. 2000-072415 describes a method for forming a crystalline carbon nitride film (C₃N₄) by sputtering using ECR (Electron Cyclotron Resonance) plasma, and proposes reduction of damage to the substrate caused by charged particles in the plasma by setting the potential of the substrate to a negative voltage in the range from −45 to −60V. Further, U.S. Pat. No. 5,849,163 proposes control of surface potential of the substrate from outside in order to reduce the damage to the substrate when epitaxially growing a thin film by sputtering. U.S. Pat. No. 5,849,163 is directed to epitaxial growth of Si.

Japanese Unexamined Patent Publication No. 2000-072415 and U.S. Pat. No. 5,849,163, however, describe an optimum condition when growing a substance of one or two types of elements by sputtering. For a substance of three or more elements, it is known that the acquisition of a thin film of desired composition by sputtering is difficult because of variation in the composition due to difference in sputtering rate among the elements.

In contrast, the present invention is directed to a substance of at least three elements, as shown by General Expression (P). The inventors of the present invention have found out that, when growing a PZT film of four or five elements, it is most important to prevent re-evaporation of Pb having a high sputtering rate and revealed an optimum condition for the adequate composition from the standpoint of surface potential Vsub of the substrate and film forming temperature.

In Japanese Unexamined Patent Publication No. 2000-072415, the potential of the substrate is changed within a negative range by changing the pressure. It does not describe pressure condition for causing the substrate to have a positive potential, which, in fact, is thought not to exist. In contrast, the inventors of the present invention have found out that, when forming a film of Pb containing perovskite oxide represented by General Expression (P), Pb element is likely to re-evaporate and when the surface potential of the substrate is set to a large negative voltage (Vsub=−10V), the film is not likely to have a perovskite structure. That is, the inventors of the present invention have found out that it is necessary to set the surface potential of the substrate to not smaller than −10V in order to obtain a perovskite oxide. Further, it has also been found out that piezoelectric performance and durability are dramatically improved by setting Vsub to a value not smaller than +5V. On the other hand, it has been found out that the arc discharge becomes abnormal if the potential of the substrate is set to a value not smaller than 100V.

Further, it is described in Japanese Unexamined Patent Publication No. 2000-072415 that the potential of the substrate holder is controlled as “the potential of the substrate”, while in the present invention, the potential of the substrate surface is controlled. Although a Pb containing perovskite oxide is a nonconductor, a low resistance layer is formed at initial stage of film forming due to lack of oxygen, so that the potential of the substrate surface is controlled even when a film is stacked thereon.

For film forming of C₃N₄, weak C—N bonds are broken by slightly increasing ion energy impinging on the substrate in order to leave only strong C—N bonds. For this purpose, the potential of the substrate is set to a negative value in Japanese Unexamined Patent Publication No. 2000-072415 to make the ion energy impinging on the substrate relatively large. However, the inventors of the present invention have found that, when growing a Pb containing perovskite oxide film, prevention of Pb re-evaporation is more important than giving the energy contributing to the growth and it is desirable to set the potential of the substrate to a positive value.

The perovskite oxides represented by General Expression (P) above include lead containing compounds, such as lead titanate, lead zirconate titanate (PZT), lead zirconate, lead lanthanum titanate, lead lanthanum zirconate titanate, lead magnesium niobate zirconate titanium, and lead nickel niobate zirconate titanium, and non-lead compounds, such as barium titanate, bismuth sodium titanate, bismuth potassium titanate, sodium niobate, potassium niobate, and lithium niobate. The piezoelectric film may be a mixed crystal system of those represented by General Expression (P) above.

The present invention is preferably applicable to the PZT system represented by General Expression (P-1) or B-site substituted PZT system, and a mixed crystal system of these.

Pbₐ(Zr_{b1}Ti_{b2}X_{b3})O₃ (P-1)

(where, X is at least one type of metal element selected from a group consisting of V and VI family elements, and a>0, b1>0, b2>0, and b3=0. Typically, a=1.0 and b1+b2+b3=1.0, but these values may deviate from 1.0 within a range in which a perovskite structure is obtainable.)

The perovskite oxide represented by General Expression (P-1) above is lead zirconate titanate (PZT) when d=0, and an oxide obtained by replacing a portion of B-site of PZT with X which is at least one metal element selected from a group consisting of V and VI family elements. X may be any metal element of VA, VB, VIA, and VIB families. Preferably, it is at least one type of element selected from a group consisting of V, Nb, Ta, Cr, Mo and W.

The inventors of the present invention have found out that, when forming a piezoelectric film of perovskite oxide represented by General Expression (P) above, a perovskite crystal does not grow favorably and a film mainly formed of pyrochlore phases is formed under the film forming condition of Ts (° C.)<400, which does not satisfy Formula (1) above, because the film forming temperature is too low, while a perovskite crystal does not grow under the film forming condition of 550<Ts (° C.) (FIG. 10).

Further, the inventors of the present invention have found out that, when forming a piezoelectric film of perovskite oxide represented by General Expression (P) above, if surface potential Vsub of the substrate is −10=Vsub (V)<100 when film forming temperature Ts is 400=Ts (° C.)=550, pyrochlore phase suppressed perovskite crystals can be stably grown and Pb dropout is stably prevented, whereby a quality piezoelectric film with high crystalline orientation can be formed (FIG. 10).

The inventors of the present invention have found out that a perovskite crystal can be grown by setting Vsub not smaller than −10 when the film forming temperature is in the range of Formula (1) above, but have confirmed that Vsub (V) not smaller than 100 causes the arc discharge abnormal in the film forming chamber and a stable plasma space can not be produced.

Values of plasma potential Vp obtained by simulation when surface potential Vsub of the substrate is controlled are shown in Table 1 below.

TABLE 1

| Substrate Surface Potential Vsub (V) | Plasma Potential Vp (V) |
|---|---|
| 40 | 105 |
| 0 | 65 |
| −40 | 25 |

As shown in Table 1, when Vsub is varied, Vp is also varied following the Vsub variations to a certain degree, and the difference between Vp and Vsub is substantially constant.

Based on the results described above, the inventors of the present invention have found out that the appropriate plasma state for obtaining a perovskite structure is the sate in which both Vsub and Vp are relatively high.

According to the film forming method of the present invention, desirable ranges of two factors (Ts and Vsub) that influence the film property are set and a film is formed under the desirable film forming condition so that a quality piezoelectric film may be formed stably by sputtering. Employment of the film forming method of the present invention allows the condition for forming quality films to be found easily, and when forming piezoelectric films of perovskite oxides, pyrochlore phase suppressed perovskite crystals can be stably grown and Pb dropout is stably prevented.

### [Piezoelectric Film]

Application of the film forming method of the present invention may provide the following piezoelectric film. That is, according to the piezoelectric film forming method of the present invention, a piezoelectric film of one or more types of perovskite oxides represented by General Expression (P) below may be obtained.

AₐB_{b}O3 (P)

(where, A is at least one type of A-site element containing Pb, B is at least one type of B-site element selected from a group consisting of Ti, Zr, V, Nb, Ta, Cr, Mo, W, Mn, Sc, Co, Cu, In, Sn, Ga, Zn, Cd, Fe, and Ni, and O is oxygen element. Typically, a=1.0 and b=1.0, but these values may deviate from 1.0 within a range in which a perovskite structure is obtainable).

According to the present invention, a quality piezoelectric film having pyrochlore phase suppressed perovskite crystals, with Pb dropout being prevented, and favorable crystalline structure and film composition may be provided stably.

According to the present invention, a piezoelectric film of 1.0=a, having composition without Pb dropout may be provided. It may also provide a piezoelectric film of 1.0<a, having Pb rich composition. There is not any specific upper limit for a, and the inventors of the present invention have found out that a piezoelectric film having favorable piezoelectric performance can be obtained when 1.0=a=1.3.

### [Piezoelectric Device and Inkjet Recording Head]

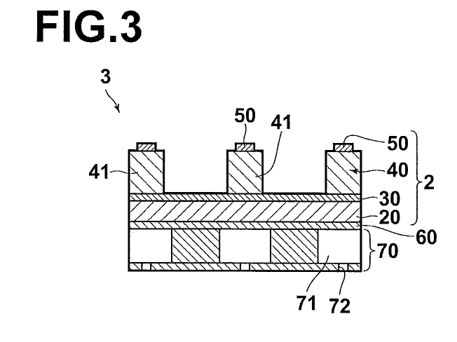

The structure of a piezoelectric device having a piezoelectric film formed by the film forming method according to an embodiment of the present invention and an inkjet recording head (liquid discharge device) having the piezoelectric device will be described with reference to FIG. 3. FIG. 3 is a cross-sectional view (cross-sectional view in the thickness direction of the piezoelectric device) of a relevant part of the inkjet recording head. Each of the components is not necessarily drawn to scale for facilitating visibility.

Piezoelectric device 2 of the present embodiment is a device which includes lower electrode 30, piezoelectric film 40, and upper electrode 50 stacked on substrate 20 in this order and an electric field is applied in the thickness direction by lower electrode 30 and upper electrode 50.

Lower electrode 30 is formed on substantially the entire surface of substrate 20, then patterned piezoelectric film 40 in which line-like convexes 41 extending from the front to rear of the drawing are disposed in a stripe shape, and upper electrode 50 is formed on each convex 41.

The pattern of piezoelectric film 40 is not limited to that shown in FIG. 3, and any pattern may be designed as appropriate. Further, piezoelectric film 40 may be a continuous film. But, a patterned piezoelectric film formed of a plurality of separate convexes is preferable, rather than a continuous film, since each convex stretches or contracts smoothly, thereby providing a greater amount of displacement.

As for substrate 20, there is not any specific limitation on the material, and, for example, silicon, glass, stainless (SUS), yttrium-stabilized zirconia (YSZ), alumina, sapphire, or silicon carbide may be used.

There is not any limitation on the major component of lower electrode 30 and, for example, a metal, such as Au, Pt, Ir, IrO₂, RuO₂, LaNiO₃, or SrRuO₃, a metal oxide, or a combination thereof may be used.

There is not any limitation on the major component of upper electrode 50 and, for example, a material listed for lower electrode 30, an electrode material generally used for semiconductor processing, such as Al, Ta, Cr, or Cu, or a combination thereof may be used.

Piezoelectric film 40 is a film formed by the film forming method of the present invention described above. Preferably, piezoelectric film 40 is formed of a perovskite oxide represented by General Expression (P) above.

There is not any specific limitation on the thickness of lower electrode 30 and upper electrode 50 and, for example, about 200 nm. There is not any specific limitation on the film thickness of piezoelectric film 40 and normally not smaller than 1 μm, for example, 1 to 5 μm.

Inkjet recording head (liquid discharge device) 3 basically constituted by an ink nozzle (liquid storage/discharge member) 70, having an ink chamber (liquid chamber) 71 for storing an ink and an ink discharge opening 72, attached to the bottom surface of substrate 20 via vibration plate 60. A plurality of ink chambers 71 is provided according to the number and pattern of convexes 41 of piezoelectric film 40.

In inkjet recording head 3, electric fields applied to convexes 41 of piezoelectric device 2 are increased or decreased with respect to each convex 41 to cause it to stretch or contract, thereby controlling the ink discharges and the amounts thereof.

Piezoelectric device 2 and inkjet recording head 3 are configured in the manner described above.

### [Inkjet Recorder]

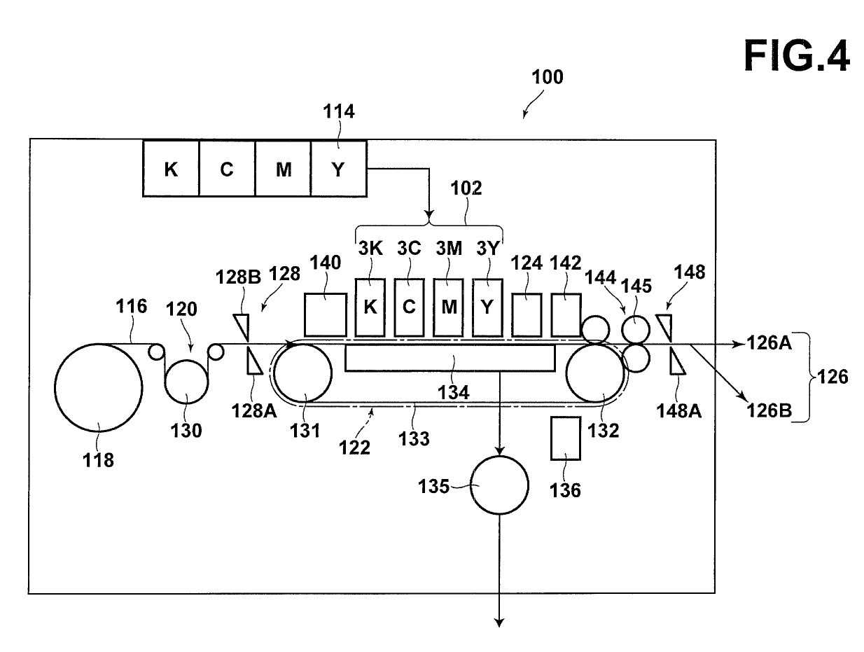

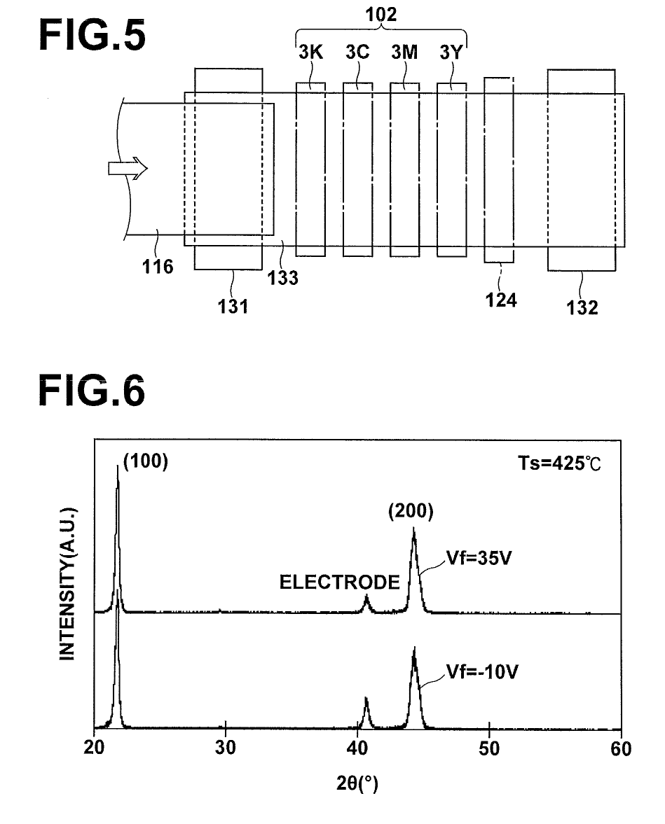

An example configuration of an inkjet recorder having an inkjet recording head 3 according to the embodiment described above will be described with reference to FIGS. 4 and 5. FIG. 4 is an overall view and FIG. 5 is a partial top view of the recorder.

Illustrated inkjet recorder 100 basically includes print section 102 having a plurality of inkjet recording heads (hereinafter, simply “heads” or “head”) 3K, 3C, 3M, and 3Y, each for each ink color, ink storage/mount section 114 for storing inks to be supplied to each of heads 3K, 3C, 3M, and 3Y, paper feed section 118 for feeding recording paper 116, decurling section 120 for decurling recording paper 116, suction belt conveyor 122, disposed opposite to the nozzle surface (discharge surface) of print section 102, for conveying recording paper 116 while maintaining flatness of recording paper 116, print detection section 124 for reading a result of printing performed by print section 102, and paper discharge section 126 for discharging a printed paper (printed material) to the outside.

Each of Heads 3K, 3C, 3M, and 3Y constituting print section 102 corresponds to inkjet recording head 3 according to the embodiment described above.

In decurling section 120, recording paper 116 is heated by heating drum 130 in the direction opposite to the curled direction of recording paper 116 wound on a roll.

For a system that uses a roll paper, cutter 128 for cutting the roll paper is provided at a latter stage of decurling section 120, as illustrated in FIG. 4, and the roll paper is cut out to a desired size. Cutter 128 includes fixed blade 128A having a length greater than the width of the conveyor path and round blade 128B that moves along fixed blade 128A, in which fixed blade 128A is provided on the rear side of the printing surface and round blade 128B is provided on the printing surface side across the conveyor path. A system that uses a cut sheet does not require cutter 128.

Decurled and cut recording paper 116 is fed to suction belt conveyor 122. Suction belt conveyor 122 includes rollers 131, 132, and endless belt 133 wound between them, and configured such that at least the portion opposite to the nozzle surface of print section 102 and the sensor surface of print detection section 124 becomes a level plane (flat plane).

Belt 133 has a width greater than that of recording paper 116 and many suction holes are formed in the belt face. Suction chamber 134 is provided at the position opposite to the nozzle surface of print section 102 and the sensor surface of print detection section 124 in the inner side of belt 133 wound between rollers 131, 132. Suction chamber 134 is suctioned by fan 135 so as to have a negative pressure, thereby suction-holding recording paper 116 on belt 133.

Power is supplied to at least either one of rollers 132, 133 from a motor (not shown), whereby belt 133 is driven in clockwise direction in FIG. 4 and recording paper 116 held on belt 133 is conveyed from left to right in FIG. 4.

When a borderless print or the like is printed, the ink also adheres to belt 133, so that belt cleaning section 136 is provided at a predetermined position (appropriate position other than the printing area) on the outer side of belt 133.

Heating fan 140 is provided on the upstream side of print section 102 on the paper conveyer path formed by suction belt conveyor 122. Heating fan 140 blows heated air onto recording paper 116 before printing to heat recording paper 116. By heating recording paper 116 immediately preceding the printing, spotted inks on recording paper 116 are dried faster.

Print section 102 is a so-called full line head in which line heads having a length corresponding to a maximum paper width are disposed in a direction (main scanning direction) orthogonal to the paper feed direction (FIG. 5). Each of printing heads 3K, 3C, 3M, and 3Y is a line head having a plurality of ink discharge openings (nozzles) disposed over a length which exceeds at least one side of maximum size of recording paper 116.

Heads 3K, 3C, 3M, and 3Y corresponding to black (K), cyan (C), magenta (M), and (yellow) respectively are disposed in this order from the upstream side along the paper feed direction of recording paper 116. A color image is recorded on recording paper 116 by discharging a color ink from each of heads 3K, 3C, 3M, and 3Y while conveying recording paper 116.

Print detection section 124 is constituted by a line sensor or the like for imaging inkjet results of print section 102 to detect an inkjet fault, such as clogging of a nozzle, from the obtained inkjet image.

Post drying section 142 constituted by a heating fan or the like for drying the printed image surface is provided at the latter stage of print detection section 124. It is desirable that the printed surface avoids any contact until the inks are dried, so that a method of blowing heated air is preferable.

Heating/pressing section 144 for controlling the glossiness of an image surface is provided at the latter stage of post drying section 142. In heating/pressing section 144, the image surface is pressed, while being heated, by pressing rollers 145 having a predetermined uneven surface shape to transfer the uneven shape to the image surface.

The printed material obtained in the manner described above is discharged from paper discharge section 126. Preferably, an intended print (print on which an intended image is printed) and a test print are discharged separately. Inkjet recorder 100 includes a selection means (not shown) for selecting and switching paper discharge paths between intended prints and test prints to send them discharge section 126A and 126B respectively. Where an intended image and a test image are printed on a large paper in parallel at the same time, cutter 148 may be provided to separate the test print portion.

Inkjet recorder 100 is structured in the manner as described above.

### (Design Change)

The present invention is not limited to the embodiment described above, and may be changed in design without departing from the sprit of the present invention.

### EXAMPLE

Example 1 and Comparative Examples 1 and 2 of the present invention will now be described.

### Example 1

First, a Ti adhesion layer of 10 nm thickness and an Ir lower electrode of 150 nm thickness were formed on an SOI substrate by sputtering with a substrate temperature of 350° C. to provide a substrate having an electrode.

Using the sputtering system shown in FIG. 1, a piezoelectric film was formed on the substrate (lower electrode) with a thickness of 4 μm while maintaining potential Vsub of the lower electrode on the substrate (potential of the substrate surface) at a constant value by floating the substrate. A film forming gas of 99% Ar and 1% O₂ and a target material of Pb_{1.3}((Zr_{0.52}Ti_{0.48})_{0.9}Nb_{0.1})) were used to form an Nb-doped PZT piezoelectric film. Hereinafter, Nb-doped PZT is referred to as “Nb-PZT”.

When film forming temperature Ts was varied within the range from 400 to 550° C. with surface potential Vsub of the substrate set to −10V or 35V, favorable perovskite crystal structures with sparse pyrochlore phases were obtained. X-ray analysis (XRD) patterns of Nb-PZT films formed at 425, 450, and 475° C. are shown in FIGS. 6, 7, and 8 respectively.

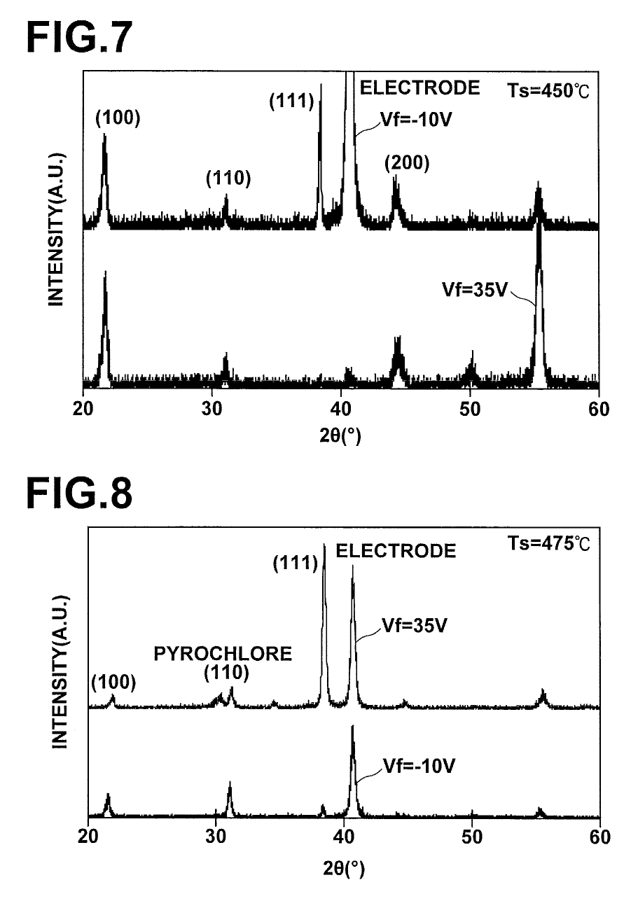

As shown in FIGS. 6 and 7, orientations other than (100) orientation were observed when film forming temperature Ts was set to 450° C., since migration elements on the substrate have a higher energy in comparison with the case in which film forming temperature Ts was set to 425° C.

As shown in FIG. 8, in the case in which film forming temperature was set to 475° C., a favorable perovskite crystal structure was obtained without any pyrochlore phase with Vsub of −10V during the film forming. In the mean time, when Vsub is set to 35V, pyrochlore phases were observed slightly, but the piezoelectric performance was at a level satisfactory for practical use.

Among Nb-PZT films obtained by the film forming method described above, samples formed by varying film forming temperatures Ts from 425 to 550° C. with substrate surface temperature Vsub being set to −10V or 35V were used to produce open pool structures having a 1.1 mm opening, and piezoelectric constant d31 (pm/V) was measured for them from the amounts of displacement when driven by 30V, the results of which are shown in Table 2. The piezoelectric constant d31 indicates the elongation or contraction in a direction along the electrode surface, which is essentially a negative value but expressed in an absolute value hereinafter.

As shown in Table 2, each of the samples has a piezoelectric constant in the range from 190 to 270 pm/V. As for the upper electrode, Pt/Ti formed by sputtering was used. Samples having a piezoelectric constant greater than or equal to 250 pm/V are those formed at a temperature in the range from 450 to 525° C., showing that this temperature range is preferable.

TABLE 2

| | Temp. | | | | | |
|---|---|---|---|---|---|---|
| Vsub | 425° C. | 450° C. | 475° C. | 500° C. | 525° C. | 550° C. |
| −10 V | 200 | 270 | 260 | 260 | 250 | 190 |
| +35 V | 200 | 260 | 270 | 250 | 250 | 210 |

### Comparative Example 1

An SOI substrate having a lower electrode of Ti/Ir was provided as in Example 1, and Nb-PZT was formed by sputtering with a thickness of 4 μm. Here, the film forming was performed while maintaining potential Vsub of the lower electrode on the substrate at a constant value by floating the substrate as in Example 1.

When Vsub was set to −35V, pyrochlore phases were observed at each of film forming temperatures of 425, 450, and 475° C.

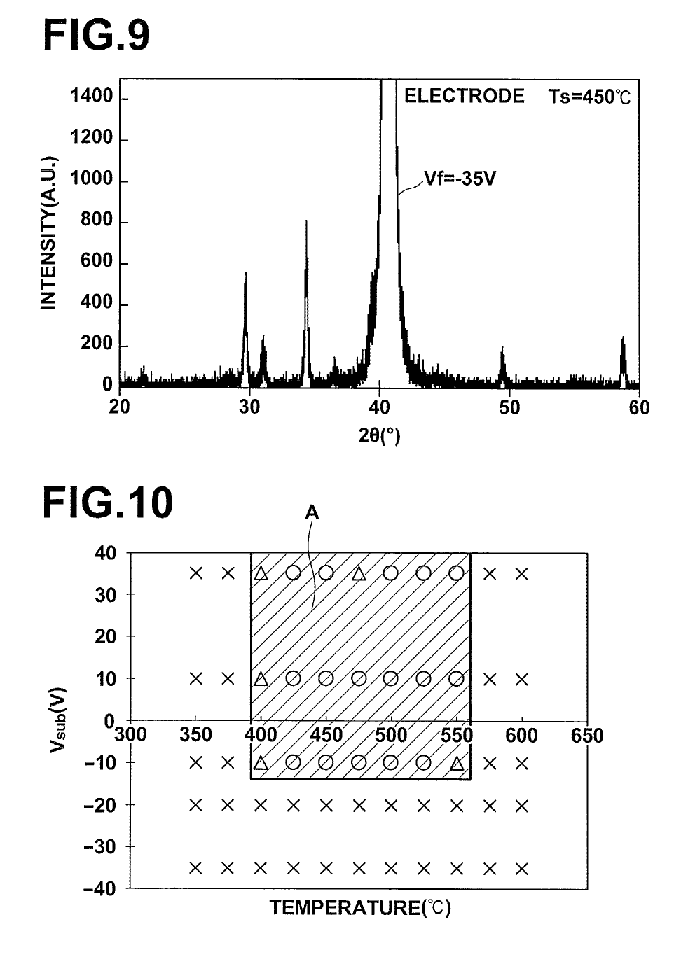

Further, each film obtained here had severe detachments and cracks to an extent that the film was not unusable as a device. An X-ray analysis (XRD) pattern of an Nb-PZT film formed at a film forming temperature of 450° C. with Vsub of −35V is shown in FIG. 9. FIG. 9 clearly shows that no perovskite crystal structure is formed.

### Comparative Example 2

Nb-PZT films were formed at film forming temperatures Ts of 350 and 375° C. under substantially the same condition as Example 1. Here, pyrochlore phases were observed at any value of surface potential Vsub of the substrate.

Further, when Nb-PZT films were formed at film forming temperatures Ts of 575 and 600° C., no perovskite layer was obtained at any value of surface potential Vsub of the substrate.

### Comparative Example 3

When plasma was generated by setting surface potential Vsub of the substrate to +100V, an abnormal arc discharge occurred and stable plasma was not obtained.

### Summary of Example 1 and Comparative Examples 1 and 2

FIG. 10 summarizes the film quality evaluations obtained by XRD measurement results of the samples in Example 1, Comparative Example 1 and Comparative Example 2 with the horizontal axis representing film forming temperature Ts and vertical axis representing surface potential Vsub of the substrate. In FIG. 10, film samples having a perovskite crystal structure with crystal orientation are evaluated as good (o), those mainly formed of pyrochlore phases are evaluated as bad (x), and those having pyrochlore phases sparsely but with piezoelectric performance comparable to that of a sample evaluated as good are evaluated as usable (A).

FIG. 10 shows that perovskite crystals are obtained in an area defined by film forming temperature range from 400 to 550° C. and substrate surface potential Vsub of not smaller than −10V (shaded area A in FIG. 10). It is thought that an appropriate plasma state for a perovskite oxide to grow can be created by controlling surface potential Vsub of the substrate. Generally, the potential distribution when plasma is generated differs depending on the inner chamber structure of the sputtering system. But control of the surface potential of the substrate to an appropriate value in the manner as described above allows a perovskite crystal to be obtained regardless of the configuration of the sputtering system. Where a metal target is used, it is known that it is effective to apply a negative bias to the substrate in order to improve stress and adhesion. On the other hand, where a nonconductive target, such as piezoelectric body is used, it has been thought not to be effective because the substrate surface gradually becomes not biased as the film is built up. In the Example and Comparative Examples, a nonconductive body is used as the target, but a highly conductive oxygen poor metallic layer is grown in a region of about 50 nm in an early phase of the growth, so that it is effective to apply a constant voltage to the substrate surface. Further, when obtaining a Pb system perovskite oxide by sputtering, it is known that the region of about 50 nm in an early stage of growth has smallest robustness, and hence it can be thought that if the growth of that portion is controlled properly by the application of a bias to the substrate, a perovskite structure is obtainable even the substrate surface is insulated and becomes not biased after that.

As described above, it has been confirmed that piezoelectric films having high crystal orientation and a favorable perovskite structure can be obtained stably by performing film forming within a range that satisfies film forming temperature Ts, 400=Ts (° C.) =550° C. and surface temperature Vsub of the substrate, −10=Vsub (V)<100V. Further, it has been confirmed that 425=Ts (° C.)=525° C. is preferable and 450=Ts (° C.)=525° C. is more preferable.

### <Durability Test>

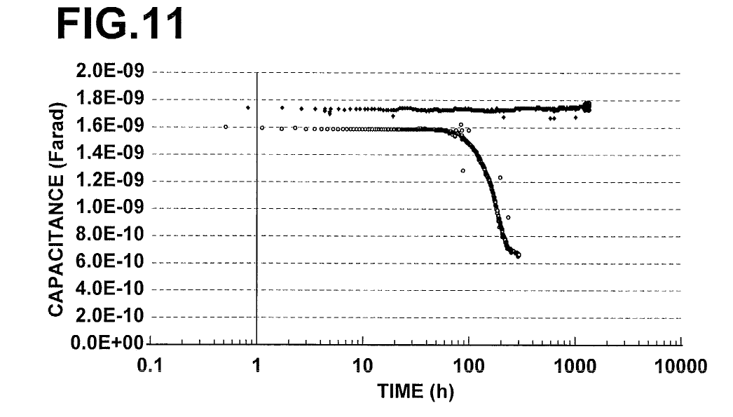

FIG. 11 shows durability comparison results between a sample formed with Vsub=5V (indicated by black circles in FIG. 11) and a sample formed with Vsub=−10V (indicated by white circles) of those of Example 1 described above. FIG. 11 shows capacitance variations of the samples with time. As shown in FIG. 11, the capacitance of the sample formed with Vsub=5V does not change for more than 1000 hours, while the capacitance of the sample formed with Vsub=−10V decreases sharply at around 100 hours. This proves that a piezoelectric film formed with the surface potential of the substrate not lower than 5V has high durability.

What is claimed is:

1. A film forming method for forming a piezoelectric film of one or more types of perovskite oxides represented by General Expression (P) below on a substrate by sputtering using plasma, wherein film forming is performed under a film forming condition in which a film forming temperature Ts (° C.) and a surface potential Vsub of the substrate satisfy Formulae (1) and (2) below respectively.
AₐB_{b}O₃ (P)
(where, A is at least one type of A-site element containing Pb, B is at least one type of B-site element selected from a group consisting of Ti, Zr, V, Nb, Ta, Cr, Mo, W, Mn, Sc, Co, Cu, In, Sn, Ga, Zn, Cd, Fe, and Ni, and O is an oxygen element. Typically, a=1.0 and b=1.0, but these values may deviate from 1.0 within a range in which a perovskite structure is obtainable.)
400=Ts (° C.)=550 (1)
−10=Vsub (V)<100 (2)

2. The film forming method of claim 1, wherein the film forming condition satisfies 425=Ts (° C.)=525°

3. The film forming method of claim 2, wherein the film forming condition satisfies 450=Ts (° C.)=525°

4. The film forming method of claim 1, wherein the piezoelectric film is formed of one or more types of perovskite oxides represented by General Expression (P-1) below.
Pbₐ(Zr_{b1}Ti_{b2}X_{b3})O₃ (P-1)
(where, X is at least one type of metal element selected from a group consisting of V and VI family elements, and a>0, b1>0, b2>0, and b3=0. Typically, a=1.0 and b1+b2+b3=1.0, but these values may deviate from 1.0 within a range in which a perovskite structure is obtainable.)
